(19) United States
(12) Patent Application Publication
(10) Pub. No.: US 2021/0230733 A1
(43) Pub. Date: Jul. 29, 2021

(54) Mask and Evaporation Apparatus

(71) Applicant: BOE Technology Group Co., Ltd., Beijing (CN)

(72) Inventors: Kui ZHANG, Beijing (CN); Shengji YANG, Beijing (CN)

(21) Appl. No.: 16/960,550

(22) PCT Filed: Feb. 14, 2020
(86) PCT No.: PCT/CN2020/075291

§ 371 Date: Jul. 8, 2020

(30) Foreign Application Priority Data
Apr. 1, 2019 (CN) 201910256621.9

(51) Int. Cl. C23C 14/04; C23C 14/24

(52) U.S. Cl. CPC C23C 14/04; C23C 14/24

(57) ABSTRACT

Provided are a mask and an evaporation apparatus. The mask includes a mask body provided with an evaporation hole; the mask body is further provided with a dust receiving recess, the dust receiving recess and the evaporation hole have a common side wall therebetween, and the common side wall separates the dust receiving recess from the evaporation hole.

### CROSS-REFERENCE TO RELATED APPLICATIONS

The present application is a U.S. National Phase Entry of International Application No. PCT/CN2020/075291 having an international filing date of Feb. 14, 2020, which claims the priority to the Chinese Patent Application No. 201910256621.9, filed to the CNIPA on Apr. 1, 2019 and entitled “Mask and Evaporation Apparatus”. The above-identified applications are incorporated into this application by reference in their entirety.

### TECHNICAL FIELD

Embodiments of the present application relate to, but are not limited to, a mask and an evaporation apparatus.

### BACKGROUND

In an Organic Light-Emitting Diode (OLED) display device, the fabrication of organics requires the use of a mask. In an evaporation process with a mask, attention should be paid to two aspects, one is that there is a certain distance between the mask and a substrate, and evaporation particles have a certain component velocity in the horizontal direction, which will produce an evaporation shadow; and the other is that dust is inevitable in the evaporation process, which requires a dust prevention design.

### SUMMARY

The following is a summary of the subject matter described in detail herein. This summary is not intended to limit the protection scope of the claims.

In one aspect, an embodiment of the present application provides a mask, including a mask body having an evaporation hole and a dust receiving recess, the dust receiving recess and the evaporation hole having a common side wall therebetween, and the common side wall separating the dust receiving recess from the evaporation hole.

In an exemplary embodiment, an opening of the evaporation hole on a side away from an evaporation source is smaller than an opening thereof on a side close to the evaporation source.

In an exemplary embodiment, the dust receiving recess includes an annular groove, and the evaporation hole is located on an inner side of a region enclosed by the annular groove.

In an exemplary embodiment, a width of the annular groove is 100 μm to 300 μm.

In an exemplary embodiment, a side of the annular groove facing away from the evaporation hole is closed or open.

In an exemplary embodiment, a width of the common side wall is 100 μm to 1 mm.

In an exemplary embodiment, the dust receiving recess includes a non-annular groove.

In an exemplary embodiment, a diameter of the non-annular groove is 0.1 μm to 3 μm.

In an exemplary embodiment, the dust receiving recess includes multiple non-annular grooves, and the multiple non-annular grooves are uniformly arranged in a circumferential direction of the evaporation hole.

In another aspect, an embodiment of the present application provides an evaporation apparatus, including the mask described in any one of the above embodiments.

Other aspects will become apparent upon reading and understanding accompanying drawings and the detailed description.

### BRIEF DESCRIPTION OF DRAWINGS

The accompanying drawings are used to provide a further understanding of the technical solutions of the embodiments of the present application and form a part of the specification. Together with the embodiments of the present application, they are used to explain the technical solutions and do not constitute a limitation on the technical solutions.

FIG. 1 is a schematic sectional view of a dust prevention scheme of a mask.

FIG. 2 is a schematic sectional view of a mask during evaporation according to an embodiment of the present application.

FIG. 3 is a schematic sectional view of a mask during evaporation according to another embodiment of the present application.

FIG. 4 is a schematic sectional view of a mask during evaporation according to a further embodiment of the present application.

The corresponding relationship between reference signs and part names in FIGS. 2 to 4 is as follows:

1—Mask body, 11—Evaporation hole, 12—Dust receiving recess, 13—Common side wall, 14—Second side wall, 2—Evaporation source, and 3—Substrate.

### DETAILED DESCRIPTION

Embodiments of the present application will be described below in detail with reference to the accompanying drawings. It should be noted that the embodiments in the present application and the features in the embodiments can be combined with each other arbitrarily if there is no conflict.

In the following description, numerous specific details are set forth in order to facilitate a full understanding of the present application. However, the present application may be implemented in other ways than those described here. Therefore, the protection scope in this document is not restricted by the specific embodiments disclosed below.

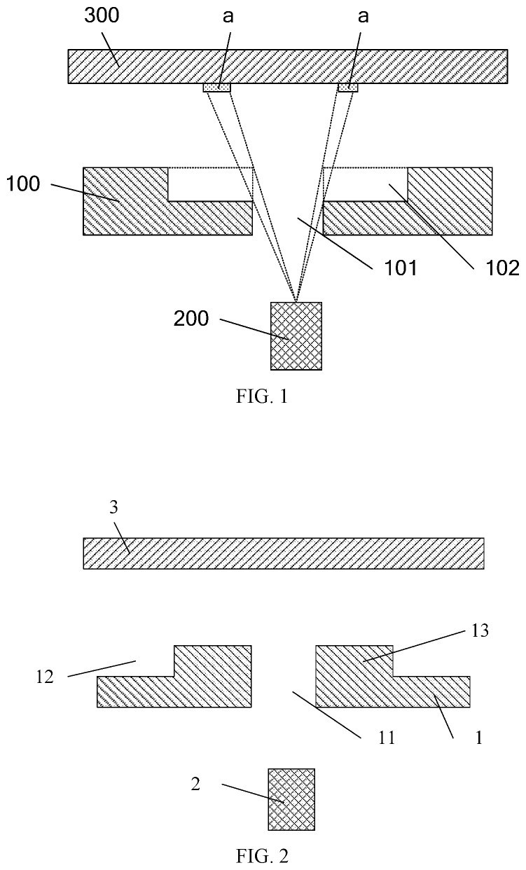

As shown in FIG. 1, in a dust prevention scheme of a mask, a counter bore 102 (semi-etched hole) is provided at an evaporation hole 101 on a mask body 100, the evaporation hole 101 is located on a bottom wall of the counter bore 102, and the bottom wall of the counter bore 102 other than the evaporation hole 101 is used for receiving dust. With this scheme, the distance between the evaporation hole 101 and a substrate 300 (which is greater than the distance between the mask and the substrate 300) is increased, so an evaporation shadow formed will be increased (refer to the position a in FIG. 1 for an increased evaporation shadow). In FIG. 1, the reference sign 200 denotes an evaporation source.

As shown in FIGS. 2 to 4, a mask according to an embodiment of the present application includes a mask body 1 provided with an evaporation hole 11, the mask body 1 is also provided with a dust receiving recess 12 having a common side wall 13 with the evaporation hole 11, and the common side wall 13 separates the dust receiving recess 12 from the evaporation hole 11.

For a mask according to an embodiment of the present application, the mask body 1 thereof is provided with an evaporation hole 11 and a dust receiving recess 12, the dust receiving recess 12 and the evaporation hole 11 have a common side wall 13 therebetween, and the common side wall 13 separates the dust receiving recess 12 from the evaporation hole 11, i.e., the dust receiving recess 12 and the evaporation hole 11 are separated from each other. During evaporation, dust is received by the dust receiving recess 12, which can reduce dust particle pollution in the evaporation process, greatly improving the yield of product.

In an exemplary embodiment, an opening of the evaporation hole 11 on a side away from an evaporation source is smaller than or equal to an opening thereof on a side close to the evaporation source. In this embodiment, the distance between the mask and the substrate 3 is the distance between the evaporation hole 11 and the substrate 3. In this way, an evaporation shadow formed will not be increased.

In another exemplary embodiment, an opening of the evaporation hole 11 on a side away from an evaporation source may be larger than an opening thereof on a side close to the evaporation source.

In an exemplary embodiment, the dust receiving recess 12 is a receiving groove. During evaporation, the receiving groove can receive dust so that dust is received in the receiving groove to reduce the dust content in the evaporation environment, thereby reducing dust particle pollution during evaporation and greatly improving the yield of product.

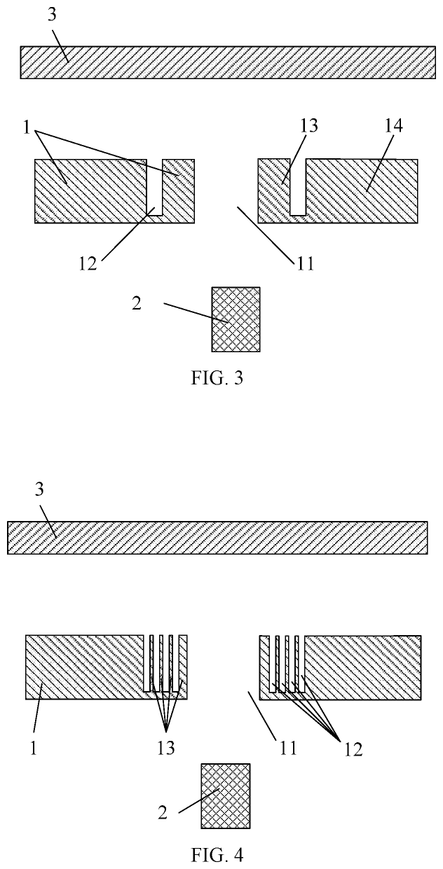

In an exemplary embodiment, as shown in FIGS. 2 and 3, the receiving groove is an annular groove, and the evaporation hole 11 is located on an inner side of a region enclosed by the annular groove. The common side wall 13 between the annular groove and the evaporation hole 11 is used to ensure that the distance between the mask and the substrate 3 is the distance between the evaporation hole 11 and the substrate 3, so that an evaporation shadow formed will not be increased.

In an exemplary embodiment, the width of the annular groove can be set to 100 μm to 300 μm, the distance between the evaporation hole 11 and the annular groove can be set to 100 μm to 1 mm, that is, the width of the common side wall 13 can be set to 100 μm to 1 mm. These parameters can all be adjusted as needed.

In an exemplary embodiment, as shown in FIG. 3, a side of the annular groove facing away from the evaporation hole 11 is closed, that is, a second side wall 14 is provided at a side of the annular groove facing away from the evaporation hole 11, and the annular groove is between the second side wall 14 and the common side wall 13.

In an exemplary embodiment, as shown in FIG. 2, the side of the annular groove facing away from the evaporation hole 11 can be open, i.e., a stage structure with the center protruding and the surrounding recessed is formed on the mask, and the evaporation hole 11 is located on the central protrusion of the stage structure.

In an exemplary embodiment, the receiving groove includes multiple annular grooves, and the evaporation hole 11 is located on an inner side of a region enclosed by each annular groove.

In another exemplary embodiment, as shown in FIG. 4, the receiving groove is a non-annular groove, and the non-annular groove is provided beside and close to the evaporation hole 11. The common side wall 13 between the non-annular groove and the evaporation hole 11 is used to ensure that the distance between the mask and the substrate 3 is the distance between the evaporation hole 11 and the substrate 3. This scheme will not increase the distance between the evaporation hole 11 and the substrate 3, and in this way, an evaporation shadow formed will not be increased.

In an exemplary embodiment, the diameter of the non-annular groove is 0.1 μm to 3 μm. During evaporation, the non-annular groove can receive dust so that dust is contained in the non-annular groove to reduce the dust content in the evaporation environment, which can reduce the dust particle pollution in the evaporation process and greatly improve the yield of product. The particle size of dust is about 0.3 μm to 0.5 μm.

In an exemplary embodiment, the receiving groove may be circular, square, or in other shapes.

In an exemplary embodiment, the non-annular groove is a blind hole with one end open and the other end closed.

In an exemplary embodiment, the non-annular groove is a through hole penetrating the mask body 1. A through hole can receive more dust than a blind hole.

In an exemplary embodiment, as shown in FIG. 4, the receiving groove includes multiple non-annular grooves. The position and number of the non-annular grooves are determined according to requirements.

In an exemplary embodiment, the shapes of the multiple non-annular grooves are the same or different.

In an exemplary embodiment, the multiple non-annular grooves are uniformly arranged in a circumferential direction of the evaporation hole 11. In this way, it is possible to better receive dust, and reduce dust particle pollution in the evaporation process, thereby greatly improving the yield of product.

In an exemplary embodiment, the multiple non-annular grooves may be formed by laser fine etching.

In an exemplary embodiment, the dust receiving recess 12 may include one or more annular grooves and one or more non-annular grooves, and the evaporation hole 11 is located on an inner side of a region enclosed by each annular groove.

An embodiment of the present application provides an evaporation apparatus (see FIGS. 2 to 4), including the mask according to any one of the above embodiments.

The evaporation apparatus according to an embodiment of the present application has all advantages of the mask described in any one of the above embodiments, which will not be repeated here.

As shown in FIGS. 2 to 4, the evaporation apparatus further includes an evaporation source 2, which may be a crucible or the like. During evaporation, the substrate 3 is located above the mask, the evaporation source 2 is located below the mask, the dust receiving recess 12 is located on an upper surface of the mask, and the opening of the dust receiving recess 12 faces upward and faces the substrate 3.

To sum up, for the mask according to an embodiment of the present application, the mask body thereof is provided with an evaporation hole and a dust receiving recess, the dust receiving recess and the evaporation hole have a common side wall therebetween, and the common side wall separates the dust receiving recess from the evaporation hole, i.e., the dust receiving recess and the evaporation hole are disposed to be separated from each other. During evaporation, dust is received by the dust receiving recess, which can reduce dust particle pollution in the evaporation process, greatly improving the yield of product. Moreover, the distance between the mask and the substrate is the distance between the evaporation hole and the substrate, so that the evaporation shadow formed will not be increased.

In the description of the present application, the term “install”, “link”, “connect”, “fix” or the like should be broadly interpreted, for example, “connect” may be connected fixedly, connected detachably, or integrated; and may be direct connected, or indirectly connected through an intermediary. Those of ordinary skills in the art can understand the specific meanings of the above terms in the present application according to specific situations.

In the description of this specification, the description with reference to the terms “an embodiment”, “some embodiments”, “specific embodiments” and the like means that a specific feature, structure, material, or characteristic described in connection with the embodiment or example is included in at least one embodiment or example of the present application. In this specification, schematic illustration of the above terms is not necessarily directed to the same embodiment or example. Moreover, the specific features, structures, materials, or characteristics described may be combined in any one or more embodiments or examples in a proper way.

Although embodiments of the present disclosure have been described above, the described contents are only the embodiments for facilitating understanding of the present application, which are not intended to limit the present application. Any person skilled in the art to which the present application pertains can make any modifications and variations in the form and details of implementation without departing from the spirit and scope of the present application. Nevertheless, the scope of patent protection of the present application shall still be subject to the scope defined by the appended claims.

What we claim is:

1. A mask, comprising a mask body having an evaporation hole, a dust receiving recess and a common side wall between the dust receiving recess and the evaporation hole, the common side wall separating the dust receiving recess from the evaporation hole.

2. The mask according to claim 1, wherein an opening of the evaporation hole on a side away from an evaporation source is smaller than or equal to an opening of the evaporation hole on a side close to the evaporation source.

3. The mask according to claim 1, wherein the dust receiving recess comprises an annular groove, and the evaporation hole is located on an inner side of a region enclosed by the annular groove.

4. The mask according to claim 3, wherein a width of the annular groove is 100 μm to 300 μm.

5. The mask according to claim 3, wherein a side of the annular groove facing away from the evaporation hole is closed or open.

6. The mask according to claim 3, wherein a width of the common side wall is 100 μm to 1 mm.

7. The mask according to claim 1, wherein the dust receiving recess comprises a non-annular groove.

8. The mask according to claim 7, wherein a diameter of the non-annular groove is 0.1 μm to 3 μm.

9. The mask according to claim 7, wherein the dust receiving recess comprises a plurality of non-annular grooves, and the plurality of non-annular grooves are uniformly arranged in a circumferential direction of the evaporation hole.

10. An evaporation apparatus, comprising the mask according to claim 1.

11. The mask according to claim 4, wherein a width of the common side wall is 100 μm to 1 mm.

12. The mask according to claim 5, wherein a width of the common side wall is 100 μm to 1 mm.
